(19) United States
(12) Patent Application Publication
(10) Pub. No.: US 2021/0141509 A1
(43) Pub. Date: May 13, 2021

(54) DISPLAY DEVICE, SYSTEM TO DETECT DISCONNECTION AND METHOD FOR DETECTING DISCONNECTION

(71) Applicant: SHARP KABUSHIKI KAISHA, Osaka (JP)

(72) Inventors: NAOYA OKADA, Sakai City (JP); KOTA MORI, Sakai City (JP)

(21) Appl. No.: 17/072,758

(22) Filed: Oct. 16, 2020

Related U.S. Application Data
(60) Provisional application No. 62/934,319, filed on Nov. 12, 2019.

(51) Int. Cl. G06F 3/041; H05K 1/11; H05K 1/02; G01R 31/71; G06F 3/044

(52) U.S. Cl. CPC G06F 3/04164; H05K 1/118; H05K 2201/09672; G01R 31/71; G06F 3/044; H05K 1/0268

(57) ABSTRACT

A display device includes: a plurality of electrode wires formed in a touch panel; a plurality of signal wires connecting together opposing ends of each of the electrode wires and a connecting circuit board connected to the touch panel; and a plurality of circuit board terminals formed on the connecting circuit board, each of the circuit board terminals being connected to a corresponding one of the signal wires, wherein the circuit board terminals include: a first circuit board terminal connected at one end to one of the electrode wires; and a second circuit board terminal connected at an other end to the one electrode wire, the first circuit board terminal and the second circuit board terminal being different.

### CROSS-REFERENCE TO RELATED APPLICATION

The present application claims priority from U.S. Provisional Application Ser. No. 62/934,319, filed Nov. 12, 2019, the content of which is hereby incorporated by reference into this application.

### BACKGROUND OF THE INVENTION

### 1. Field of the Invention

The present invention relates to a display device including a touch panel, a system to detect the presence or absence of disconnection of wiring in the display device, and a method for detecting the disconnection.

### 2. Description of the Related Art

Portable communications terminals in recent years such as smartphones and tablets are often equipped with a touch panel as an input unit. While touch panels include, for example, capacitive, resistive, and infrared touch panels, those commonly used for portable communications devices are capacitive touch panels.

Some of the capacitive touch panels utilizes so-called loop wiring; wires extending from opposing ends of electrode wires are collected together in a flexible printed circuit (FPC) to be connected to the touch panel, and each of the electrode wires corresponds to one of circuit board terminals. (e.g., Japanese Unexamined Patent Application Publication No. 2016-149120 and Japanese Unexamined Patent Application Publication No. 2010-039816). Compared with a capacitive touch panel without loop wiring, a capacitive touch panel with loop wiring can halve the number of circuit board terminals.

Moreover, Japanese Unexamined Patent Application Publication No. 2013-127787 describes a configuration in which both faces of a touch panel circuit board act as a connecting terminal.

### SUMMARY OF THE INVENTION

In the typical techniques utilizing the above loop wiring, measuring a capacitance (a capacitance check) of the circuit is the only way to check for disconnection of the wiring in the touch panel. When there is one disconnection in the loop wiring, no change in capacitance is observed. Hence, the capacitance check cannot find the presence or absence of disconnection of the wiring.

In view of the above problem, an aspect of the present invention is intended to provide a display device allowing for reliably detecting the presence or absence of disconnection of wiring in a disconnection check, while the number of circuit board terminals is reduced as seen in the loop wiring.

(1) An aspect of the present invention is directed to a display device including a touch panel. The display device includes: a plurality of electrode wires formed in the touch panel; a plurality of signal wires connecting together opposing ends of each of the electrode wires and a connecting circuit board connected to the touch panel; and a plurality of circuit board terminals formed on the connecting circuit board, each of the circuit board terminals being connected to a corresponding one of the signal wires, wherein the circuit board terminals include: a first circuit board terminal connected at one end to one of the electrode wires; and a second circuit board terminal connected at an other end to the one electrode wire, the first circuit board terminal and the second circuit board terminal being different.

(2) In the display device of another aspect of the present invention according to the above configuration (1), the first circuit board terminal and the second circuit board terminal are each positioned on one of an upper face and a lower face of the connecting circuit board to correspond to each other.

(3) Another aspect of the present invention is directed to a system to detect disconnection. The system includes: the display device according the above configurations (1) and (2); a resistance measurer measuring a resistance between circuit board terminals each formed on one of an upper face and a lower face of the connecting circuit board, the upper face and the lower face corresponding to each other; and a disconnection detector detecting presence or absence of disconnection, of the signal wires connected to the circuit board terminals, in accordance with a value measured by the resistance measurer.

(4) In the system of another aspect of the present invention according to the above configuration (3), the disconnection detector detects the presence or absence of the disconnection in accordance with the value measured by the resistance measurer, and determines a degree of the disconnection.

(5) In the system of another aspect of the present invention according to the above configuration (4), the disconnection detector determines the degree of the disconnection in two or more stages.

(6) Another aspect of the present invention is directed to a method for detecting presence or absence of disconnection of wiring of a display device including a touch panel. A plurality of signal wires connect together: opposing ends of a plurality of electrode wires formed in the touch panel; and a connecting circuit board connected to the touch panel. Each of the signal wires is connected to a corresponding one of a plurality of circuit board terminals formed on the connecting circuit board. The circuit board terminals includes: a first circuit board terminal connected at one end to one of the electrode wires; and a second circuit board terminal connected at an other end to the one electrode wire. The first circuit board terminal and the second circuit board terminal are different. The method includes: measuring a resistance between the first circuit board and the second circuit; and determining presence or absence of the disconnection using the measured resistance.

According to an aspect of the present invention, opposing ends of an electrode wire are provided with different circuit board terminals. Measuring a resistance between the circuit board terminals makes it possible to achieve advantageous effects of readily and reliably detecting the presence or absence of disconnection of a signal wire including the electrode wire.

### BRIEF DESCRIPTION OF THE DRAWINGS

FIG. 1 illustrates an example of a wiring structure of a touch panel included in a display device according to an embodiment of the present invention.

FIG. 2 illustrates an example of a relationship, in an FPC, between a signal wire from each electrode and a circuit board terminal.

FIG. 3 illustrates a side view of an FPC 10, showing an example of a relationship, in the FPC 10, between a signal wire from each electrode and a circuit board terminal.

FIG. 4 illustrates a method for detecting disconnection of wiring.

FIG. 5 illustrates an example of a disconnection in signal wiring of a touch panel.

FIG. 6 illustrates a flowchart of a process of the method for detecting disconnection of wiring.

FIG. 7 illustrates an example of a typical loop wiring structure.

### DETAILED DESCRIPTION OF THE INVENTION

### First Embodiment

Described below in detail is an embodiment of the present invention. A display device 1 according to this embodiment includes a touch panel.

(A Wiring Structure of a Touch Panel)

Described first is a wiring structure of the touch panel, with reference to FIG. 1. FIG. 1 illustrates an example of the wiring structure of the touch panel. As illustrated in FIG. 1, arranged in an interior of a face of the touch panel are X-axis electrode wires (X1 to X15) and Y-axis electrode wires (Y1 to Y40). For example, the electrode wire X1 is disposed in the X-axis direction between a left electrode XL-1 and a right electrode XR-1. In a similar manner, the electrode wire X2 is disposed in the X-axis direction between a left electrode XL-2 and a right electrode XR-2. Hereinafter, in the example illustrated in FIG. 1, the arranged X-axis electrode wires include the electrode wires X1 to X15.

Moreover, the electrode wire Y1 is disposed in the Y-axis direction between an upper electrode YU-1 and a lower electrode YL-1. In a similar manner, the electrode wire Y2 is disposed in the Y-axis direction between an upper electrode YU-2 and a lower electrode YL-2. Hereinafter, in the example illustrated in FIG. 1, the arranged Y-axis electrode wires include the electrode wires Y1 to Y40. Note that the X-axis direction and the Y-axis direction in this embodiment are respectively referred to as a longitudinal direction and a lateral direction of the touch panel. Furthermore, FIG. 1 illustrates the X-axis electrode wires X1 and X15 and the Y-axis electrode wires Y1 and Y40 alone. Note that the electrode wires are provided in any given number. In FIG. 1, the number of the electrode wires is, but not limited to, 15 in the X-axis direction and 40 in the Y-axis direction.

The left electrodes (the XL-1 to the XL-15), the right electrodes (the XR-1 to the XR-15), the upper electrodes (the YU-1 to the YU-40), and the lower electrodes (the YL-1 to the YL-40) have signal wires (XLS, XRS, YUS, and YLS) extending therefrom and connected to a flexible printed circuit (FPC) 10. That is, the FPC 10 is a connecting circuit board conductively connected to the touch panel. In the example illustrated in FIG. 1, connected to the FPC 10 are: a signal wire XLS-1 from the left electrode XL-1; a signal wire XRS-1 from the right electrode XR-1; a signal wire YUS-1 from the upper electrode YU-1; and a signal wire YLS-1 from the lower electrode YL-1.

(A Wiring Structure of the FPC)

Described next with reference to FIGS. 2 and 3 is a relationship between circuit board terminals (an XT-1) of the FPC 10 and the signal wires (XLS, XRS, YUS, and YLS) extending from the electrodes (the left electrodes (the XL-1 to the XL-15), the right electrodes (the XR-1 to the XR-15), the upper electrodes (the YU-1 to the YU-40), and the lower electrodes (the YL-1 to the YL-40)). FIGS. 2 and 3 illustrate an example of a relationship, in the FPC 10, between a signal wire from each electrode and a circuit board terminal.

On an electrode-wire basis of the touch panel, each of the signal wires of the touch panel is connected to a corresponding one of the circuit board terminals of the FPC 10. For example, as illustrated in FIG. 2, signal wires (an XLS-1 and an XRS-1) extend from electrodes (the left electrode XL-1 and the right electrode XR-1) at opposing ends of the electrode wire X1. The extending signal wires are connected to the circuit board terminal XT-1 of the FPC 10.

In this embodiment, the circuit board terminals are provided to an upper face and a lower face of the FPC 10. For example, the signal wire XLS-1 extending from the left electrode XL-1 is connected to a circuit board terminal XT-1A provided on the upper face of the FPC 10, and the signal wire XRS-1 extending from the right electrode XR-1 is connected to a circuit board terminal XT-1B provided on the lower face of the FPC 10. (See FIG. 3.)

Note that FIGS. 2 and 3 illustrate a configuration corresponding to the electrode wire X1 alone. The FPC 10 includes a configuration corresponding to the electrode wires provided to the touch panel. That is, as illustrated in FIG. 1, when the touch panel includes a total electrode wires of 55 including the X1 to the X15 and the Y1 to the Y40, the FPC 10 also includes a total circuit board terminals of 55 including the XT-1 to the XT-15 on the upper surface of the FPC 10 and the YT-1 to the YT-40 on the lower surface of the FPC 10.

Described here is a structure of a typical FPC 10′, with reference to FIG. 7. FIG. 7 illustrates an example of a typical loop wiring structure. In the typical loop wiring illustrated in FIG. 7, the signal wire XLS-1 extending from the left electrode XL-1 and the signal wire XRS-1 extending from the right electrode XR-1 are connected together in the FPC 10′, and further connected to one circuit board terminal XT′-1. Hence, in the loop wiring, for example, the XT′-1 is the only circuit board terminal to be connected to the electrode wire X1. Thus, the only way to check for disconnection of the wiring is to measure a capacitance of the circuit.

Meanwhile, in this embodiment, the example described above shows the following: the circuit board terminals XT-1A and the XT-1B are connected to the electrode wire X1; the circuit board terminal XT-1A is connected through the signal wire XLS-1 to the left electrode XL-1; and the circuit board terminal XT-1B is connected through the signal wire XRS-1 to the right electrode XR-1.

Hence, the circuit board terminal XT-1A, the signal wire XLS-1, the left electrode XL-1, the X-axis electrode wire X1, the right electrode XR-1, the signal wire XRS-1, and the circuit board XT-1B form a single closed circuit. Thus, simply measuring a resistance between the circuit board terminals XT-1A and XT-1B can detect the presence or absence of disconnection of the closed circuit; that is, the presence or absence of disconnection of wires (the signal wire XLS-1 and the signal wire XRS-1) connected to the X-axis electrode wire X1.

As can be seen, the display device 1 according to this embodiment includes a touch panel. The display device 1 includes: a plurality of electrode wires (the X1 to the X15, and the Y1 to the Y40) formed in the touch panel; a plurality of signal wires (the XLS, the XRS, the YUS, and the YLS) connecting together opposing ends of each of the electrode wires and a connecting circuit board (the FPC 10) connected to the touch panel; and a plurality of circuit board terminals (the XT) formed on the connecting circuit board, each of the circuit board terminals being connected to a corresponding one of the signal wires, wherein the circuit board terminals include: a first circuit board terminal connected at one end to one of the electrode wires; and a second circuit board terminal connected at an other end to the one electrode wire, the first circuit board terminal and the second circuit board terminal being different. That is, the first circuit board terminal and the second circuit board terminal are each positioned on one of an upper face and a lower face of the connecting circuit board to correspond to each other.

(A Method for Detecting Disconnection of Wiring)

Described next is a method for detecting disconnection of wiring of the touch panel according to this embodiment, with reference to FIGS. 4 to 6. FIG. 4 illustrates a side view of the FPC 10, showing a method for detecting disconnection of wiring. Note that the wiring of the touch panel includes as a concept the electrode wires of the touch panel and the signal wires connected to the electrode wires.

In detecting disconnection of the wiring of the touch panel, as illustrated in FIG. 4, a resistance is measured between the circuit board terminal XT-1A provided on the upper face of the FPC 10 and the circuit board terminal XT-1B provided, on the lower face of the FPC 10, to correspond to the circuit board terminal XT-1A. The example in FIG. 4 shows that the resistance is measured by a resistance meter (a resistance measurer) 50. Then, using a value measured by the resistance meter 50, a disconnection detector 70 detects the presence or absence of disconnection of the wiring. Hence, a system including the FPC 10 connected to the touch panel of the display device 1, the resistance meter 50, and the disconnection detector 70 can be referred to as a system to detect disconnection.

When there is no disconnection in the wiring, the resistance meter 50 should present a measured value lower than or equal to a predetermined value. Hence, if the resistance meter 50 presents a measured value higher than the predetermined value, it can be determined that the wiring is disconnected somewhere.

Note that FIG. 4 illustrate a configuration to detect the presence or absence of disconnection of the wiring including the electrode wire X1. A similar configuration can detect the presence or absence of disconnection of wiring including another electrode wire. Note that the presence or absence of the disconnection may be determined with a resistance to be measured for each corresponding circuit board terminal. Alternatively, a plurality of resistance meters may be used to simultaneously detect the presence or absence of disconnections among a plurality of wires.

As can be seen, in the configuration according to this embodiment, a resistance is measured between circuit board terminals provided on the upper face and the lower face of the circuit board. Such a feature makes it possible to readily and reliably detect the presence or absence of disconnection of wiring.

Meanwhile, in the case of the typical loop wiring described above, even though there is one disconnection in the wiring, the disconnection cannot be detected. For example, as illustrated in FIG. 5, the signal wire XLS-1 is assumed to have a disconnection C. Here, in the configuration according to this embodiment, a resistance between the circuit board terminals XT-1A and XT-1B exceeds the predetermined value. Hence, the disconnection C can be detected. In the case of the loop wiring, however, the circuit board terminal XT′-1 (see FIG. 7) is connected through the signal wire XRS-1 to the electrode wire X1. Hence, even if the signal wire XLS-1 has a disconnection, a capacitance measured at the circuit board terminal XT′-1 does not change by the presence or absence of the disconnection.

Moreover, circuit board terminals are each positioned on one of the upper face and the lower face of the FPC 10 to correspond to each other, and a pair of the circuit board terminals on the upper and lower faces acts as one terminal. Hence, the number of the circuit board terminals for the FPC 10 can be the same as that for the typical loop wiring.

As can be seen, the system according to this embodiment detects disconnection of wiring. The system includes: the display device 1; a resistance measurer (the resistance meter 50) measuring a resistance between circuit board terminals each formed on one of an upper face and a lower face of the connecting circuit board, the upper face and the lower face corresponding to each other; and the disconnection detector 70 detecting presence or absence of disconnection, of the signal wires connected to the circuit board terminals, in accordance with a value measured by the resistance measurer.

Described next is a process of a method for detecting disconnection of wiring. FIG. 6 illustrates a flowchart of the process of the method for detecting disconnection of wiring.

As seen in FIG. 6, first, selected are circuit board terminals of touch panel wiring whose disconnection is to be detected (S101). At S102, a resistance is measured between the selected circuit board terminals on the upper and lower faces (S102: measuring a resistance). At S103, the disconnection detector 70 determines whether the measured resistance exceeds a predetermined value (S103: determining the presence or absence of disconnection). If the resistance exceeds the predetermined value (S103: YES), the disconnection detector 70 determines that disconnection is found in the touch panel wiring (S104). If the resistance is below or equal to the predetermined value (S103: NO), the disconnection detector 70 determines that no disconnection is found in the touch panel wiring (S105).

### Second Embodiment

Described below is another embodiment of the present invention. Note that, for the sake of description, constituent features having the same function between the first embodiment and this embodiment are denoted with the same reference signs. Such constituent features will not be repeatedly elaborated upon.

In the above first embodiment, the disconnection detector 70 determines the presence or absence of disconnection by whether the resistance measured by the resistance meter 50 exceeds a predetermined value. In this embodiment, the disconnection detector 70 not only detects the presence or absence of disconnection of wiring but also determines a degree of the disconnection.

For example, if the resistance meter 50 measures a resistance in the mega ohm (e.g., 1 MΩ) when a resistance without disconnection is 100 Ω, the disconnection detector 70 determines that the wiring is disconnecting; that is, the wiring is partially disconnected. If the resistance meter 50 measures a resistance greater than or equal to 1 MΩ, the disconnection detector 70 determines that the wiring is disconnected.

Such a feature makes it possible not only to detect the presence or absence of disconnection of wiring but also to determine a degree of the disconnection.

Moreover, the disconnection detector 70 may determine the degree of the disconnection in two or more stages. For example, the disconnection detector 70 may determine that: the wiring is slightly disconnected if the resistance meter 50 measures a resistance in the kilo ohm; the wiring is severely disconnected if the resistance meter 50 measures a resistance in the mega ohm; and the wiring is completely disconnected if the resistance meter 50 measures a resistance in the mega ohm or above.

Software Implementation

The disconnection detector 70 may be implemented by logic circuits (hardware) fabricated, for example, in the form of an integrated circuit (IC chip), and may be implemented by software.

In the latter form of implementation, the disconnection detector 70 includes a computer that executes instructions from programs; that is, software by which various functions are implemented. This computer includes, for example, at least one processor (controller) and at least one computer-readable storage medium containing the above programs. The processor in the computer then retrieves and runs the programs contained in the storage medium, thereby achieving the object of the present invention. The above processor may be, for example, a central processing unit (CPU). The storage medium may be a “non-transitory, tangible medium” such as a read-only memory (ROM), a tape, a disc/disk, a card, a semiconductor memory, or programmable logic circuitry. The computer may further include a random access memory (RAM) for loading the programs. The programs may be supplied to the computer via any transmission medium (e.g., over a communications network or by broadcasting waves) that can transmit the programs. The present invention, in an aspect thereof, encompasses data signals on a carrier wave that are generated during electronic transmission of the programs.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device including a touch panel, the display device comprising:
a plurality of electrode wires formed in the touch panel;
a plurality of signal wires connecting together opposing ends of each of the electrode wires and a connecting circuit board connected to the touch panel; and
a plurality of circuit board terminals formed on the connecting circuit board, each of the circuit board terminals being connected to a corresponding one of the signal wires, wherein
the circuit board terminals include: a first circuit board terminal connected at one end to one of the electrode wires; and a second circuit board terminal connected at an other end to the one electrode wire, the first circuit board terminal and the second circuit board terminal being different.

2. The display device according to claim 1, wherein
the first circuit board terminal and the second circuit board terminal are each positioned on one of an upper face and a lower face of the connecting circuit board to correspond to each other.

3. A system to detect disconnection, the system comprising:
the display device according to claim 1;
a resistance measurer configured to measure a resistance between circuit board terminals each formed on one of an upper face and a lower face of the connecting circuit board, the upper face and the lower face corresponding to each other; and
a disconnection detector configured to detect presence or absence of disconnection, of the signal wires connected to the circuit board terminals, in accordance with a value measured by the resistance measurer.

4. The system according to claim 3, wherein
the disconnection detector detects the presence or absence of the disconnection in accordance with the value measured by the resistance measurer, and determines a degree of the disconnection.

5. The system according to claim 4, wherein
the disconnection detector determines the degree of the disconnection in two or more stages.

6. A method for detecting presence or absence of disconnection of wiring of a display device including a touch panel,
a plurality of signal wires connecting together: opposing ends of a plurality of electrode wires formed in the touch panel; and a connecting circuit board connected to the touch panel, each of the signal wires being connected to a corresponding one of a plurality of circuit board terminals formed on the connecting circuit board, the circuit board terminals including: a first circuit board terminal connected at one end to one of the electrode wires; and a second circuit board terminal connected at an other end to the one electrode wire, and the first circuit board terminal and the second circuit board terminal being different, the method comprising:
measuring a resistance between the first circuit board and the second circuit; and
determining presence or absence of the disconnection using the measured resistance.
